(19) United States
(12) Patent Application Publication
(10) Pub. No.: US 2025/0140732 A1
(43) Pub. Date: May 1, 2025

(54) UNDERFILL MATERIAL, SEMICONDUCTOR PACKAGE AND METHOD FOR PRODUCING SEMICONDUCTOR PACKAGE

(71) Applicant: RESONAC CORPORATION, Tokyo (JP)

(72) Inventors: Tomoya MASUDA, Chiyoda-ku, Tokyo (JP); Ryota SATO, Chiyoda-ku, Tokyo (JP); Mayu SUZUKI, Chiyoda-ku, Tokyo (JP)

(73) Assignee: RESONAC CORPORATION, Tokyo (JP)

(21) Appl. No.: 18/837,603

(22) PCT Filed: Feb. 28, 2022
(86) PCT No.: PCT/JP2022/008375

§ 371 Date: Aug. 11, 2024

(51) Int. Cl. H01L 23/00; H01L 21/48; H01L 23/498

(52) U.S. Cl. CPC H01L 24/29; H01L 21/4803; H01L 23/49894; H01L 24/32; H01L 24/83; H01L 2224/2929; H01L 2224/29386; H01L 2224/32225; H01L 2224/83855; H01L 2924/2075

(57) ABSTRACT

An underfill material includes a curable resin component and inorganic particles. A ratio on a number basis of particles with a particle diameter of 0.5 μm or less included in the inorganic particles is 10% or less of the total inorganic particles, and a ratio on a number basis of particles with a particle diameter of 3 μm or more is 5% or less of the total inorganic particles.

### TECHNICAL FIELD

The present invention relates to an underfill material, a semiconductor package, and a method for producing a semiconductor package.

### RELATED ART

With miniaturization and thinning of electronic component devices incorporating elements such as semiconductor chips, bare chip mounting, i.e., mounting semiconductor chips (bare chips) in an unpackaged state on a substrate, has become mainstream as a mounting technique for electronic component devices.

In flip-chip mounting, which is a type of bare chip mounting in which an active surface of the semiconductor chip is connected facing a substrate side, a liquid curable resin composition called an underfill material is used to fill a void between the semiconductor chip and the substrate connected via bumps. For example, Patent Document 1 describes an underfill material that includes a multi-functional epoxy resin and a curing agent including a phenolic compound and an acid anhydride. The underfill material serves an important role in protecting the semiconductor chip from temperature, humidity, a mechanical external force, etc.

### RELATED ART DOCUMENTS

### Patent Documents

Patent Document 1: Japanese Patent Application Laid-Open No. 2004-256646

### SUMMARY OF INVENTION

### Problem to be Solved by Invention

In flip-chip type semiconductor devices, conventionally, solder balls have been mainly used as bumps connecting between the semiconductor element and the substrate. On the other hand, with the increase in the number of terminals resulting from miniaturization and high integration of semiconductor devices, copper pillars capped with solder at the tip are being adopted instead of the conventional solder balls.

Furthermore, from the viewpoint of increasing the degree of integration of semiconductor devices, development of techniques for mounting elements three-dimensionally is progressing, such as 2.XD (2.X-dimensional) mounting and 3D (three-dimensional) mounting. In these mounting techniques, an intermediate substrate formed with a through electrode called an interposer is disposed on the substrate, and elements are mounted thereon.

As the degree of integration of semiconductor devices increases, there is a tendency for voids filled with an underfill material to become narrower. Thus, there is a possibility that conventional underfill materials may not be able to sufficiently seal voids in highly integrated semiconductor devices.

This disclosure has been made in view of such circumstances, and an objective thereof is to provide an underfill material excellent in a filling property, a semiconductor package obtained using the underfill material, and a method for producing the same.

### Means for Solving Problem

The means for solving the above problem include the following embodiments.

<1> An underfill material including a curable resin component and inorganic particles, where a ratio on a number basis of particles with a particle diameter of 0.5 μm or less included in the inorganic particles is 10% or less of the total inorganic particles, and a ratio on a number basis of particles with a particle diameter of 3 μm or more is 5% or less of the total inorganic particles.

<2> The underfill material according to <1>, where the curable resin component includes an epoxy resin.

<3> The underfill material according to <2>, where the epoxy resin includes at least one type selected from a group consisting of a bisphenol type epoxy resin, a naphthalene type epoxy resin, and a tri- or higher functional glycidylamine type epoxy resin.

<4> The underfill material according to any one of <1> to <3>, including a surface treatment agent, where a coating rate of the inorganic particles coated by the surface treatment agent is 50% or more.

<5> A semiconductor package including a substrate, a semiconductor element, and a cured product of the underfill material according to any one of <1> to <4>.

<6> The semiconductor package according to <5>, where the cured product is disposed in a void between the substrate and the semiconductor element.

<7> The semiconductor package according to <5>, further including an interposer disposed between the substrate and the semiconductor element.

<8> The semiconductor package according to <7>, where the cured product is disposed in at least one selected from a group consisting of a void between the substrate and the interposer and a void between the interposer and the semiconductor element. 5<9> A method for producing a semiconductor package, including: filling at least one selected from a group consisting of a void between a substrate and a semiconductor element, a void between the substrate and an interposer, and a void between the interposer and the semiconductor element with the underfill material according to any one of <1> to <4>; and curing the underfill material.

### Effect of Invention

According to this disclosure, an underfill material excellent in a filling property, a semiconductor package obtained using the underfill material, and a method for producing the same are provided.

### BRIEF DESCRIPTION OF DRAWINGS

FIG. 1 is a scanning electron microscope image of ash of an underfill material obtained in Example 1.

FIG. 2 is a scanning electron microscope image of ash of an underfill material obtained in Example 10.

FIG. 3 is a scanning electron microscope image of ash of an underfill material obtained in Comparative Example 1.

FIG. 4 is a scanning electron microscope image of ash of an underfill material obtained in Comparative Example 2.

FIG. 5 is a scanning electron microscope image of ash of an underfill material obtained in Comparative Example 3.

FIG. 6 is a scanning electron microscope image of ash of an underfill material obtained in Comparative Example 4.

### DESCRIPTION OF EMBODIMENTS

Hereinafter, embodiments for carrying out the present invention will be described in detail. However, the present invention is not limited to the following embodiments. In the following embodiments, constituent elements thereof (including element steps and the like) are not necessarily required unless explicitly stated. The same applies to numerical values and ranges thereof, which do not limit the present invention.

In this disclosure, the term “process” includes not only a process that is independent of other processes, but also a process that cannot be clearly distinguished from other processes as long as the purpose of the process is achieved.

In this disclosure, a numerical range indicated using “A to B” includes numerical values described before and after “to” as a minimum value and a maximum value, respectively.

In numerical ranges described in stages in this disclosure, an upper limit value or a lower limit value described in one numerical range may be replaced with an upper limit value or a lower limit value of another numerical range described in stages. Further, in the numerical ranges described in this disclosure, the upper limit value or the lower limit value of the numerical range may be replaced with a value shown in Examples.

In this disclosure, each component may include multiple types of corresponding substances. In the case where multiple types of substances corresponding to each component are present in a composition, unless otherwise specified, a content ratio or a content of each component refers to a total content ratio or content of the multiple types of substances present in the composition.

In this disclosure, each component may include multiple types of corresponding particles. In the case where multiple types of particles corresponding to each component are present in a composition, unless otherwise specified, a particle diameter of each component refers to a value for a mixture of the multiple types of particles present in the composition.

### <Underfill Material>

An underfill material of this disclosure includes a curable resin component and inorganic particles. In the underfill material, a ratio on a number basis of particles with a particle diameter of 0.5 μm or less included in the inorganic particles is 10% or less of the total inorganic particles, and a ratio on a number basis of particles with a particle diameter of 3 μm or more is 5% or less of the total inorganic particles.

The underfill material of this disclosure has an excellent filling property for a narrow void compared to conventional underfill materials. One reason for this may be that a particle size distribution of the inorganic particles included in the underfill material has properties not found in a particle size distribution of inorganic particles included in conventional underfill materials.

That is, in the inorganic particles included in the underfill material of this disclosure, ratios of particles with a particle diameter of 0.5 μm or less and particles with a particle diameter of 3 μm or more in the total inorganic particles are respectively smaller than those in inorganic particles included in conventional underfill materials. This may contribute to improving the filling property of the underfill material.

### (Inorganic Particles)

In this disclosure, a ratio on a number basis of particles with a particle diameter of 0.5 μm or less and a ratio on a number basis of particles with a particle diameter of 3 μm or more in the inorganic particles are determined according to an image analysis method.

The method of image analysis is not particularly limited. Examples include a method in which inorganic particles themselves, ash (residue after removing organic components from the underfill material) of the underfill material, a dispersion liquid including inorganic particles, etc. are observed with an optical microscope or an electron microscope. Counting of the inorganic particles may be performed by visual observation or may be performed using an image analysis system.

From the viewpoint of measurement precision, the image analysis is carried out under conditions that a total number of inorganic particles to be measured is 100 or more and an observation magnification is 1000 times or more.

In this disclosure, the particle diameter of the inorganic particles is set as an equivalent circle diameter of the observed particles.

From the viewpoint of the filling property of the underfill material, the ratio on a number basis of particles with a particle diameter of 0.5 μm or less included in the inorganic particles is 10% or less, preferably 50% or less, more preferably 1% or less, and even more preferably 0.1% or less, of the total inorganic particles. The ratio on a number basis of particles with a particle diameter of 0.5 μm or less included in the inorganic particles may also be 0% of the total.

From the viewpoint of the filling property of the underfill material, the ratio on a number basis of particles with a particle diameter of 3 μm or more included in the inorganic particles is 5% or less, preferably 3% or less, more preferably 1% or less, and even more preferably 0.1% or less, of the total inorganic particles. The ratio on a number basis of particles with a particle diameter of 3 μm or more included in the inorganic particles may also be 0% of the total inorganic particles.

From the viewpoint of the filling property of the underfill material, a volume average particle diameter of the inorganic particles is preferably 0.6 μm to 2.5 μm, more preferably 0.7 μm to 2.3 μm, and even more preferably 0.8 μm to 2 μm.

The volume average particle diameter of the inorganic particles is determined according to a laser diffraction/scattering method. Specifically, the volume average particle diameter of the inorganic particles is determined as a particle diameter (D50) at which accumulation of volumes from a smaller diameter side becomes 50% in a particle size distribution on a volume basis obtained by the laser diffraction/scattering method.

The material of the inorganic particles included in the underfill material is not particularly limited. Specifically, examples include silica, alumina, calcium carbonate, zirconium silicate, calcium silicate, silicon nitride, aluminum nitride, boron nitride, beryllia, zirconia, zircon, forsterite, steatite, spinel, mullite, titania, talc, clay, mica, etc. Further, inorganic particles having a flame retardant effect may be used. Examples of the inorganic particles having a flame retardant effect include composite metal hydroxides such as aluminum hydroxide, magnesium hydroxide, and a composite hydroxide of magnesium and zinc, zinc borate, etc.

From the viewpoint of reducing a thermal expansion coefficient of a cured product of the underfill material, silica is preferable as the inorganic particles, and from the viewpoint of improving thermal conductivity, alumina is preferable.

The inorganic particles included in the underfill material may be one type only or may be two or more types. In the case where the inorganic particles included in the underfill material are two or more types, the ratio on a number basis of particles with a particle diameter of 0.5 μm or less and the ratio on a number basis of particles with a particle diameter of 3 μm or more included in the inorganic particles are values with respect to a total of the two or more types of the inorganic particles.

An amount of the inorganic particles included in the underfill material is not particularly limited. From the viewpoint of reducing the thermal expansion coefficient of the cured product of the underfill material, the amount of the inorganic particles is preferably large. For example, a content ratio of the inorganic particles is preferably 50 mass % or more, and more preferably 55 mass % or more, of the total underfill material. From the viewpoint of suppressing a viscosity increase of the underfill material, the amount of the inorganic particles is preferably small. For example, the content ratio of the inorganic particles is preferably 80 mass % or less, and more preferably 75 mass % or less, of the total underfill material.

A shape of the inorganic particles included in the underfill material is not particularly limited. From the viewpoint of the filling property of the underfill material, the inorganic particles are preferably spherical.

### (Curable Resin Component)

A type of the curable resin component included in the underfill material is not particularly limited. From the viewpoint of balance of properties of the underfill material, the underfill material preferably includes an epoxy resin and a curing agent as the curable resin component.

A type of the epoxy resin included in the underfill material is not particularly limited. Examples include a bisphenol type epoxy resin, a naphthalene type epoxy resin, a glycidylamine type epoxy resin, a hydrogenated bisphenol type epoxy resin, an alicyclic epoxy resin, an alcohol ether type epoxy resin, a cycloaliphatic type epoxy resin, a fluorene type epoxy resin, and a siloxane type epoxy resin. The epoxy resin included in the underfill material may be one type only or may be two or more types.

Among the epoxy resins described above, it is preferable to include at least one type selected from the group consisting of a bisphenol type epoxy resin, a naphthalene type epoxy resin, and a tri- or higher functional glycidylamine type epoxy resin.

A type of the bisphenol type epoxy resin is not particularly limited, and examples include a bisphenol A type epoxy resin, a bisphenol F type epoxy resin, a bisphenol AD type epoxy resin, etc. For use as the underfill material, the bisphenol type epoxy resin is preferably liquid at room temperature (25° C., the same applies below), and is more preferably a liquid bisphenol F type epoxy resin at room temperature.

A type of the naphthalene type epoxy resin is not particularly limited. The naphthalene type epoxy resin used in the underfill material is preferably liquid at room temperature. Examples of the liquid naphthalene type epoxy resin at room temperature include 1,6-bis(glycidyloxy)naphthalene.

A type of the tri- or higher functional glycidylamine type epoxy resin is not particularly limited. The tri- or higher functional glycidylamine type epoxy resin used as the underfill material is preferably liquid at room temperature.

Examples of the tri- or higher functional glycidylamine type epoxy resin that is liquid at room temperature include triglycidyl-p-aminophenol.

The underfill material may include a liquid epoxy resin at room temperature and a solid epoxy resin at room temperature. In that case, from the viewpoint of maintaining a sufficiently low viscosity, a ratio of the solid epoxy resin at room temperature is preferably 20 mass % or less of the total epoxy resin.

A type of the curing agent included in the underfill material is not particularly limited and may be selected according to the desired properties or the like of the underfill material. Examples include an amine curing agent, a phenol curing agent, an acid anhydride curing agent, a polymercaptan curing agent, a polyaminoamide curing agent, an isocyanate curing agent, a blocked isocyanate curing agent, etc. The curing agent may be one type used alone or two or more types used in combination.

The curing agent used in the underfill material is preferably liquid at room temperature and, from the viewpoint of adhesiveness to an adherend, is preferably an amine curing agent. Examples of the amine curing agent include aliphatic amine compounds such as diethylenetriamine, triethylenetetramine, n-propylamine, 2-hydroxyethylaminopropylamine, cyclohexylamine, 4,4′-diamino-dicyclohexylmethane, aromatic amine compounds such as diethyltoluenediamine, 3,3′-diethyl-4,4′-diaminodiphenylmethane, 2-methyl aniline, imidazole compounds such as imidazole, 2-methylimidazole, 2-ethylimidazole, 2-isopropylimidazole, and imidazoline compounds such as imidazoline, 2-methylimidazoline, 2-ethylimidazoline, etc. Among these, the aromatic amine compounds are preferable.

From the viewpoint of reducing respective unreacted portions, a formulation ratio between the epoxy resin and the curing agent is preferably set such that a ratio (number of functional groups of curing agent/number of epoxy groups of epoxy resin) of the number of functional groups (active hydrogen in the case of an amine curing agent) of the curing agent to the number of epoxy groups of the epoxy resin is within a range of 0.5 to 2.0, and is more preferably set such that the ratio is within a range of 0.6 to 1.3. From the viewpoint of moldability and reflow resistance, the formulation ratio is more preferably set such that the above ratio is within a range of 0.8 to 1.2.

### (Curing Accelerator)

The underfill material may include a curing accelerator. A type of the curing accelerator is not particularly limited, and may be selected according to the type of the curable resin component included in the underfill material, the desired properties of the underfill material, etc.

In the case where the underfill material includes a curing accelerator, an amount thereof is preferably 0.1 parts by mass to 30 parts by mass, and more preferably 1 part by mass to 15 parts by mass, with respect to 100 parts by mass of the curable resin component.

### (Surface Treatment Agent)

The underfill material may include a surface treatment agent. Examples of the surface treatment agent include a silane compound such as epoxy silane, phenyl silane, mercapto silane, amino silane, phenylamino silane, alkyl silane, ureido silane, and vinyl silane, a titanium compound, an aluminum chelate compound, an aluminum/zirconium compound, etc. Among these, the silane compound is preferable. The surface treatment agent may be one type used alone or may be two or more types used in combination.

Specific examples of the surface treatment agent include:
a silane compound having a phenyl group such as phenyltrimethoxysilane, dimethoxydiphenylsilane, and phenyltriethoxysilane;
a silane compound having a vinyl group such as vinyltrimethoxysilane and vinyltriethoxysilane;
a silane compound having an epoxy group such as 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, and 3-glycidoxypropyltriethoxysilane;
a silane compound having a styryl group such as p-styryltrimethoxysilane;
a silane compound having a methacryloyl group such as 3-methacryloxypropylmethyldimethoxysilane, 3-methacryloxypropyltrimethoxysilane, 3-methacryloxypropylmethyldiethoxysilane, and 3-methacryloxypropyltriethoxysilane;
a silane compound having an acryloyl group such as 3-acryloxypropyltrimethoxysilane;
a silane compound having an amino group such as N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, and hydrochloride of N-(vinylbenzyl)-2-aminoethyl-3-aminopropyltrimethoxysilane;
a silane compound having a ureido group such as 3-ureidopropyltrialkoxysilane;
a silane compound having an isocyanate group such as 3-isocyanatepropyltriethoxysilane; and
a silane compound having a mercapto group such as 3-mercaptopropylmethyldimethoxysilane and 3-mercaptopropyltrimethoxysilane, etc.

Among these silane compounds, from the viewpoint of improving the filling property of the underfill material, it is preferable to include at least one type selected from the group consisting of the silane compound having a phenyl group, the silane compound having an epoxy group, the silane compound having an amino group, and the silane compound having a methacryloyl group.

In the case where the underfill material includes a surface treatment agent, a coating rate of the inorganic particles coated by the surface treatment agent calculated according to Formula (1) below is preferably 50% or more. That is, an amount of the surface treatment agent included in the underfill material is preferably an amount with which the coating rate of the inorganic particles coated by the surface treatment agent calculated according to Formula (1) below is 50% or more.

$$Formula ( 1 ) : Coating rate ( \% ) of inorganic particles coated by surface treatment agent = ( B / A ) \times 100.$$

“A” in the formula is a surface area of the inorganic particles included in the underfill material and is calculated according to Formula (2) below. In the case where two or more types of the inorganic particles are included in the underfill material, the surface area A of the inorganic particles is a value obtained by summing up surface areas of the two or more types of the inorganic particles.

$$Formula ( 2 ) : Surface area A ( {m}^{2} ) of inorganic particles = formulation amount ( g ) of inorganic particles \times specific surface area ( {m}^{2} / g ) of inorganic particles .$$

“B” in the formula is a coating area of the inorganic particles coated by the surface treatment agent and is calculated according to Formula (3) below. In the case where two or more types of the surface treatment agents are included in the underfill material, the coating area B of the inorganic particles coated by the surface treatment agent is a value obtained by summing up coating areas of the inorganic particles coated by the two or more types of the surface treatment agents.

Coating area B (m²) of inorganic particles coated by surface treatment agent=formulation amount (g) of surface treatment agent×minimum coating area (m²/g) of surface treatment agent. Formula (3):

In the above formula, the minimum coating area of the surface treatment agent is calculated according to the following formula.

$$Minimum coating area ( {m}^{2} / g ) = ( 6.02 \times {10}^{23} \times 13 \times {10}^{- 20} ) / molecular weight of surface treatment agent .$$

In the above formula, the specific surface area of the inorganic particles is determined according to a BET method or an image analysis method.

The specific surface area of the inorganic particles based on the BET method may be measured from a nitrogen adsorption capacity of the inorganic particles in accordance with JIS Z 8830:2013.

The specific surface area of the inorganic particles based on the image analysis method may be calculated assuming that particles in the acquired image are spherical, similar to the measurement of the particle diameter described above.

When the coating rate of the inorganic particles coated by the surface treatment agent is 50% or more, the underfill material exhibits an excellent pot life (viscosity increase during storage is suppressed). This may be because as the surface of the inorganic particles included in the underfill material is sufficiently coated with the surface treatment agent, reactions of functional groups (silanol group or the like) on the surface of the inorganic particles are reduced, and adhesiveness between the inorganic particles and the surrounding curable resin component improves, thereby suppressing sedimentation of the inorganic particles.

The coating rate of the inorganic particles coated by the surface treatment agent is preferably 60% or more, more preferably 70% or more, and even more preferably 80% or more.

The coating rate of the inorganic particles coated by the surface treatment agent may be 200% or less.

### (Colorant)

The underfill material may include a colorant. Examples of the colorant include carbon black, organic dye, organic pigment, minium, and red iron oxide. The colorant may be one type used alone or may be two or more types used in combination.

In the case where the underfill material includes a colorant, an amount thereof is preferably 0.01 parts by mass to 10 parts by mass, and more preferably 0.1 parts by mass to 5 parts by mass, with respect to 100 parts by mass of the curable resin component.

In addition to the components described above, the underfill material may further include various additives known in this technical field.

### (Uses of Underfill Material)

The underfill material may be used in various mounting techniques.

For example, the underfill material may be suitably used for sealing and the like of a void between a substrate and an interposer disposed on the substrate, a void between an interposer and a semiconductor element disposed on the interposer, and a void between a substrate and a semiconductor element disposed on the substrate.

A method of filling the void using the underfill material is not particularly limited. For example, it may be performed according to a conventional method using a dispenser or the like.

From the viewpoint of the filling property, the underfill material preferably has a sufficiently low viscosity when filling. Specifically, the viscosity at 110° C. is preferably 0.5 Pa-s or less, more preferably 0.30 Pa·s or less, and even more preferably 0.20 Pa·s or less. The viscosity of the underfill material at 110° C. may be 0.05 Pa·s or more.

In this disclosure, the viscosity of the underfill material at 110° C. is a value measured under conditions of a shear rate of 32.5 (1/s) by a rheometer (e.g., “AR2000” of TA Instruments) with a 40 mm parallel plate.

From the viewpoint of handling, the underfill material preferably has a sufficiently low viscosity at room temperature. Specifically, the viscosity at 25° C. is preferably 100 Pa·s or less, more preferably 80 Pa·s or less, and even more preferably 70 Pa·s or less. The viscosity of the underfill material at 25° C. may be 5 Pa·s or more.

In this disclosure, the viscosity of the underfill material at 25° C. is a value measured according to a method described in Examples.

The underfill material of this disclosure may be suitably used for filling a relatively narrow void. For example, it may be suitably used for filling a void at which a gap (dimension in a thickness direction of a package) is 30 μm or less, a void at which a pitch (dimension in a direction perpendicular to the thickness direction of the package) is 40 μm or less, etc.

### <Semiconductor Package>

A semiconductor package of this disclosure includes a substrate, a semiconductor element, and a cured product of the underfill material described above.

The semiconductor package may include an interposer disposed between the substrate and the semiconductor element. In that case, for example, the cured product of the underfill material is disposed in at least one selected from the group consisting of a void between the substrate and the interposer and a void between the interposer and the semiconductor element.

Examples of a specific configuration of the semiconductor package include (1) to (4) below.

(1) A configuration including a substrate, a semiconductor element disposed on the substrate, and a cured product of an underfill material disposed in a void between the substrate and the semiconductor element.

(2) A configuration including a substrate, an interposer disposed on the substrate, a semiconductor element disposed on the interposer, and a cured product of an underfill material disposed in a void between the interposer and the semiconductor element.

(3) A configuration including a substrate, an interposer disposed on the substrate, a semiconductor element disposed on the interposer, and a cured product of an underfill material disposed in a void between the substrate and the interposer.

(4) A configuration including a substrate, an interposer disposed on the substrate, a semiconductor element disposed on the interposer, a cured product of an underfill material disposed in a void between the interposer and the semiconductor element, and a cured product of the underfill material disposed in a void between the substrate and the interposer.

Types of the substrate, the interposer, and the semiconductor element included in the semiconductor package are not particularly limited and may be selected from those commonly used in the art of semiconductor packages.

Examples of the interposer include a silicon interposer, a glass interposers, and an organic interposer.

The semiconductor package may be in a state in which the semiconductor element is disposed three-dimensionally, which is called 2.XD (2.X-dimensional) mounting, 3D (three-dimensional) mounting, etc. Examples of the 2.XD mounting include 2.1D mounting, 2.3D mounting, 2.5D mounting, etc.

The semiconductor package may have only the cured product of the underfill material described above as the cured product of the underfill material, or may have both the cured product of the underfill material described above and a cured product of another underfill material.

### <Method for Producing Semiconductor Package>

The method for producing the semiconductor package of this disclosure includes: filling at least one selected from the group consisting of a void between a substrate and a semiconductor element, a void between the substrate and an interposer, and a void between the interposer and the semiconductor element with the underfill material described above; and curing the underfill material.

Types of the substrate, the interposer, and the semiconductor element used in the above method are not particularly limited and may be selected from those commonly used in the art of semiconductor packages. A method of filling the void between the substrate or the interposer and the semiconductor element with the underfill material, and a method of curing the underfill material after filling are not particularly limited and may be performed according to conventional methods.

### EXAMPLES

Hereinafter, the underfill material of this disclosure will be specifically described according to Examples, but the scope of this disclosure is not limited to these Examples.

### (Preparation of Underfill Material)

The components shown in Table 1 were mixed in amounts (parts by mass) shown in Table 1 to prepare underfill materials. Details of each component are as follows.

Epoxy resin 1 . . . Liquid bisphenol F type epoxy resin, epoxy equivalent: 160 g/eq.

Epoxy resin 2 . . . Triglycidyl-p-aminophenol, epoxy equivalent: 95 g/eq.

Curing agent 1 . . . Diethyltoluenediamine, active hydrogen equivalent: 45 g/eq.

Curing agent 2 . . . 3,3′-diethyl-4,4′-diaminodiphenylmethane, active hydrogen equivalent: 63 g/eq.

Colorant . . . Carbon black, average particle diameter: 24 nm.

Surface treatment agent 1 . . . 3-glycidoxypropyltrimethoxysilane, minimum coating area: 330 m²/g.

Surface treatment agent 2 . . . Phenyltrimethoxysilane, minimum coating area: 393 m²/g.

Inorganic particle 1 . . . Spherical silica with a volume average particle diameter of 1.0 μm, a specific surface area of 3 m²/g.

Inorganic particle 2 . . . Spherical silica with a volume average particle diameter of 1.0 μm, a specific surface area of 3 m²/g.

Inorganic particle 3 . . . Spherical silica with a volume average particle diameter of 0.5 μm, a specific surface area of 5 m²/g.

Inorganic particle 4 . . . Spherical silica with a volume average particle diameter of 1.4 μm, a specific surface area of 4 m²/g.

Inorganic particle 5 . . . Spherical silica with a volume average particle diameter of 0.5 μm, a specific surface area of 5 m²/g.

Inorganic particle 6 . . . Spherical silica with a volume average particle diameter of 0.4 μm, a specific surface area of 7 m²/g.

TABLE 1

| | | Example | | | | | | | |
|---|---|---|---|---|---|---|---|---|---|
| | Unit | 1 | 2 | 3 | 4 | 5 | 6 | 7 | 8 |
| Epoxy resin 1 | Parts by mass | 50 | 50 | 50 | 50 | 50 | 50 | 50 | 50 |
| Epoxy resin 2 | Parts by mass | 50 | 50 | 50 | 50 | 50 | 50 | 50 | 50 |
| Curing agent 1 | Parts by mass | 19 | 19 | 19 | 19 | 19 | 19 | 19 | 19 |
| Curing agent 2 | Parts by mass | 26 | 26 | 26 | 26 | 26 | 26 | 26 | 26 |
| Colorant | Parts by mass | 0.15 | 0.15 | 0.15 | 0.15 | 0.15 | 0.15 | 0.15 | 0.15 |
| Surface treatment agent 1 | Parts by mass | 0.3 | 0.7 | 1.3 | 1.7 | 2.2 | 3.2 | | |
| Surface treatment agent 2 | Parts by mass | | | | | | | 0.3 | 1.3 |
| Inorganic particle 1 | Parts by mass | 219 | 219 | 221 | 221 | 219 | 221 | 219 | 221 |
| Inorganic particle 2 | Parts by mass | | | | | | | | |
| Inorganic particle 3 | Parts by mass | | | | | | | | |
| Inorganic particle 4 | Parts by mass | | | | | | | | |
| Inorganic particle 5 | Parts by mass | | | | | | | | |
| Inorganic particle 6 | Parts by mass | | | | | | | | |
| Inorganic particle ratio of particle | % | 0 | 0 | 0 | 0 | 0 | 0 | 0 | 0 |
| diameter 0.5 μm or less | | | | | | | | | |
| Inorganic particle ratio of particle | % | 0 | 0 | 0 | 0 | 0 | 0 | 0 | 0 |
| diameter 3 μm or more | | | | | | | | | |
| Surface area A of inorganic particle | m² | 657 | 657 | 663 | 663 | 657 | 663 | 657 | 663 |
| Coating area B | m² | 103 | 232 | 434 | 564 | 723 | 1059 | 123 | 517 |
| Coating rate | % | 16 | 35 | 65 | 85 | 110 | 160 | 19 | 78 |
| Viscosity (25° C., 0 h) | Pa · s | 44 | 35 | 32 | 31 | 35 | 33 | 38 | 27 |
| Pot life | % | 641 | 163 | 32 | 35 | 54 | 32 | 778 | 44 |
| Filling time | sec | 109 | 107 | 85 | 120 | 100 | 106 | 97 | 83 |
| Narrow pitch filling property | — | OK | OK | OK | OK | OK | OK | OK | OK |

| | | Example | | | Comparative Example | | | |
|---|---|---|---|---|---|---|---|---|
| | Unit | 9 | 10 | 11 | 1 | 2 | 3 | 4 |
| Epoxy resin 1 | Parts by mass | 50 | 50 | 50 | 50 | 50 | 50 | 50 |
| Epoxy resin 2 | Parts by mass | 50 | 50 | 50 | 50 | 50 | 50 | 50 |
| Curing agent 1 | Parts by mass | 19 | 19 | 19 | 19 | 19 | 19 | 19 |
| Curing agent 2 | Parts by mass | 26 | 26 | 26 | 26 | 26 | 26 | 26 |
| Colorant | Parts by mass | 0.15 | 0.15 | 0.15 | 0.15 | 0.15 | 0.15 | 0.15 |
| Surface treatment agent 1 | Parts by mass | | 2.2 | | 1.00 | 1.00 | 1.00 | |
| Surface treatment agent 2 | Parts by mass | 3.2 | | 2.2 | | | | |
| Inorganic particle 1 | Parts by mass | 221 | | | | | | |
| Inorganic particle 2 | Parts by mass | | 219 | 219 | | | | |
| Inorganic particle 3 | Parts by mass | | | | 219 | | | |
| Inorganic particle 4 | Parts by mass | | | | | 219 | | |
| Inorganic particle 5 | Parts by mass | | | | | | 219 | |
| Inorganic particle 6 | Parts by mass | | | | | | | 219 |
| Inorganic particle ratio of particle | % | 0 | 2 | 2 | 30 | 5 | 28 | 95 |
| diameter 0.5 μm or less | | | | | | | | |
| Inorganic particle ratio of particle | % | 0 | 0 | 0 | 0 | 11 | 0 | 0 |
| diameter 3 μm or more | | | | | | | | |
| Surface area A of inorganic particle | m² | 663 | 657 | 657 | 1095 | 876 | 1095 | 1533 |
| Coating area B | m² | 1262 | 723 | 861 | 330 | 330 | 330 | — |
| Coating rate | % | 190 | 110 | 131 | 30 | 38 | 30 | — |
| Viscosity (25° C., 0 h) | Pa · s | 19 | 24 | 34 | 15 | 8 | 13 | 11 |
| Pot life | % | 62 | 26 | 75 | 33 | 28 | 36 | 300 |
| Filling time | sec | 92 | 94 | 69 | 124 | 95 | 134 | Stop |
| Narrow pitch filling property | — | OK | OK | OK | NG | NG | OK | OK |

### (Observation by Scanning Electron Microscope)

The prepared underfill material was heated at 800° C. for 4 hours, and ash was observed with a scanning electron microscope (observation magnification: 5,000 times).

From the obtained images, a ratio on a number basis of inorganic particles with a particle diameter of 0.5 μm or less and a ratio on a number basis of inorganic particles with a particle diameter of 3 μm or more were respectively calculated. The results are shown in Table 1.

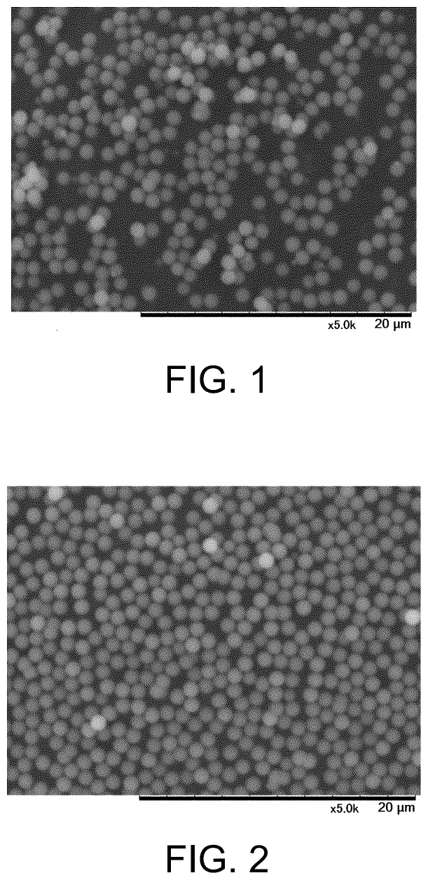

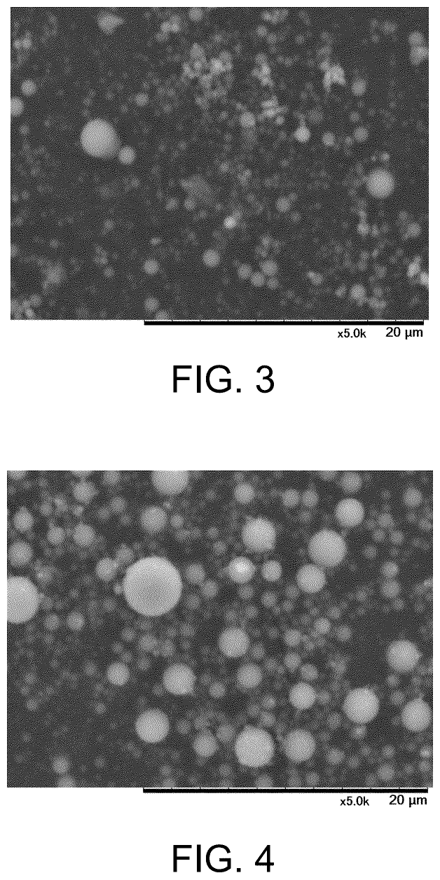

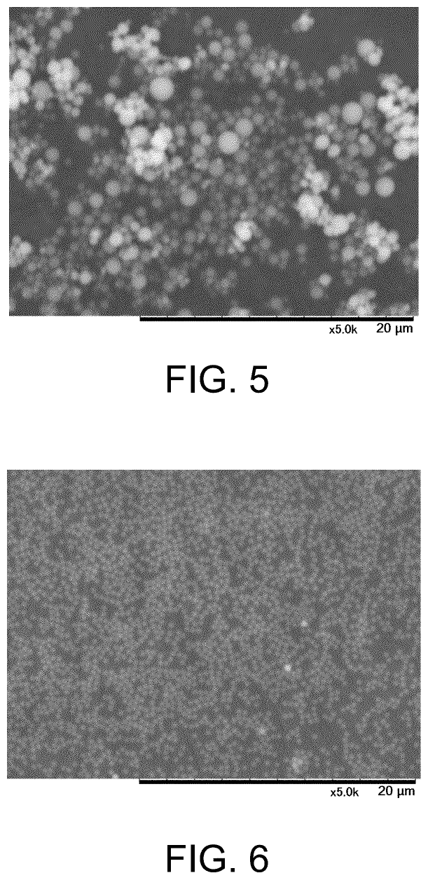

The ash of the underfill material obtained in Example 1 is shown in FIG. 1. The ash of the underfill material obtained in Example 10 is shown in FIG. 2. The ash of the underfill material obtained in Comparative Example 1 is shown in FIG. 3. The ash of the underfill material obtained in Comparative Example 2 is shown in FIG. 4. The ash of the underfill material obtained in Comparative Example 3 is shown in FIG. 5. The ash of the underfill material obtained in Comparative Example 4 is shown in FIG. 6.

### (Measurement of Viscosity)

Viscosities (Pa·s) at 25° C. immediately after preparation of the underfill material and after leaving at 25° C. for 24 hours upon preparation of the underfill material were respectively measured. The measurement was carried out using an E-type viscometer (manufactured by Tokyo Keiki Inc., VISCONIC EHD type (product name)), with a cone angle of 3° and a rotational speed of 10 revolutions per minute (rpm).

### (Evaluation of Pot Life)

A pot life (viscosity increase rate after leaving for 24 hours) was calculated from a viscosity A measured immediately after preparation of the underfill material and a viscosity B after leaving at 25° C. for 24 hours, according the following formula.

$$Pot life ( \% ) = \{ ( B - A ) / A \} \times 100.$$

### (Filling Time)

A glass plate (20 mm×30 mm×1 mm thick) was fixed on a slide glass using a spacer, and a test piece with a gap of 25 μm was prepared.

The underfill material was applied to a side surface (one side of 20 mm edge) of the glass plate on a hot plate at 110° C., and a time (seconds) for the underfill material to permeate between the slide glass and the glass plate to reach an opposite side surface of the glass plate was measured. The shorter the time to reach the opposite side surface, the better the filling property can be evaluated.

“Stop” in Table 1 means that the underfill material did not reach the opposite side surface of the glass plate.

### (Narrow Pitch Filling Property)

A test elementary group (TEG, size: 20 mm×20 mm, bump diameter: 23 μm) with copper pillar bumps was fixed on a slide glass, and a test piece with a gap of 17 μm and a pitch of 30 μm was prepared.

The underfill material was applied to one side surface (one side of 20 mm edge) of the TEG on a hot plate at 110° C., and a narrow pitch filling property of the underfill material was evaluated based on the following criteria.

OK: The underfill material reached the opposite side surface of the TEG.

NG: The underfill material did not reach the opposite side surface of the TEG.

As shown in Table 1, the underfill materials of Examples, in which the ratio on a number basis of particles with a particle diameter of 0.5 μm or less is 10% or less of the total inorganic particles, and the ratio on a number basis of particles with a particle diameter of 3 μm or more is 5% or less of the total inorganic particles, exhibited good results in both the filling time and the narrow pitch filling property.

Among Examples, Examples 3 to 6 and 8 to 11, in which the coating rate of the inorganic particles coated by the surface treatment agent is 50% or more, exhibited an excellent pot life compared to Examples 1, 2, and 7, in which the coating rate of the inorganic particles coated by the surface treatment agent is less than 50%.

The underfill materials of Comparative Examples, in which the ratio on a number basis of particles with a particle diameter of 0.5 μm or less exceeds 10% of the total inorganic particles, or the ratio on a number basis of particles with a particle diameter of 3 μm or more exceeds 5% of the total inorganic particles, had lower evaluation in either or both of the filling time and the narrow pitch filling property than Examples.

1. An underfill material comprising a curable resin component and inorganic particles, wherein a ratio on a number basis of particles with a particle diameter of 0.5 μm or less included in the inorganic particles is 10% or less of the total inorganic particles, and a ratio on a number basis of particles with a particle diameter of 3 μm or more is 5% or less of the total inorganic particles.

2. The underfill material according to claim 1, wherein the curable resin component comprises an epoxy resin.

3. The underfill material according to claim 2, wherein the epoxy resin comprises at least one type selected from a group consisting of a bisphenol type epoxy resin, a naphthalene type epoxy resin, and a tri- or higher functional glycidylamine type epoxy resin.

4. The underfill material according to claim 1, comprising a surface treatment agent, wherein a coating rate of the inorganic particles coated by the surface treatment agent is 50% or more.

5. A semiconductor package comprising a substrate, a semiconductor element, and a cured product of the underfill material according to claim 1.

6. The semiconductor package according to claim 5, wherein the cured product is disposed in a void between the substrate and the semiconductor element.

7. The semiconductor package according to claim 5, further comprising an interposer disposed between the substrate and the semiconductor element.

8. The semiconductor package according to claim 7, wherein the cured product is disposed in at least one selected from a group consisting of a void between the substrate and the interposer and a void between the interposer and the semiconductor element.

9. A method for producing a semiconductor package, comprising: filling at least one selected from a group consisting of a void between a substrate and a semiconductor element, a void between the substrate and an interposer, and a void between the interposer and the semiconductor element with the underfill material according to claim 1; and curing the underfill material.
